(19) United States
(12) Patent Application Publication
(10) Pub. No.: US 2008/0272776 A1
(43) Pub. Date: Nov. 6, 2008

(54) MAGNETIC RESONANCE IMAGE ACQUISITION WITH SUPPRESSION OF BACKGROUND TISSUES AND RF WATER EXCITATION AT OFFSET FREQUENCY

(76) Inventor: Robert R. Edelman, Highland Park, IL (US)

Correspondence Address: QUARLES & BRADY LLP, 411 E. WISCONSIN AVENUE, SUITE 2040, MILWAUKEE, WI, 53202-4497, US

(21) Appl. No.: 12/114,990

(22) Filed: May 5, 2008

Related U.S. Application Data
(60) Provisional application No. 60/915,781, filed on May 3, 2007.

(51) Int. Cl. G01R 33/48

(52) U.S. Cl. 324/307

(57) ABSTRACT

Background tissue signals such as water and/or fat are suppressed in an MR image by using an imaging agent that chemically shifts the tissue spins of interest. An imaging pulse sequence is used to acquire the image data using an RF excitation pulse that is tuned to the off-resonance tissue spins of interest with the saturation pulse sequences being interleaved with the imaging pulse sequences to selectively suppress signals from on-resonance background tissues such as water and/or fat.

### CROSS REFERENCE TO RELATED APPLICATIONS

This application is based on, incorporates herein by reference, and claims the benefit of provisional application Ser. No. 60/915,781, filed May 3, 2007, and entitled “MAGNETIC RESONANCE IMAGE ACQUISITION WITH SUPPRESSION OF BACKGROUND TISSUES AND RF WATER EXCITATION AT OFFSET FREQUENCY.”

### FIELD OF THE INVENTION

The field of the invention is magnetic resonance imaging (MRI) methods and systems and particularly the use of tissue suppression in conjunction with the use of an RF excitation pulse for water at an offset or off-resonance frequency. That is an RF excitation pulse for water at a frequency that is shifted from a nominal Larmor frequency of water.

### BACKGROUND OF THE INVENTION

Any nucleus that possesses a magnetic moment attempts to align itself with the direction of a magnetic field in which it is located. In doing so, however, the nucleus precesses around this direction at a characteristic frequency that is termed the Larmor frequency, f₀, and that is dependent on the strength of the magnetic field and on the gyromagnetic constant γ of the nucleus: i.e., f₀=γB, where γ=42.56 MHz/T for hydrogen nuclei, and B is the strength of the magnetic field. Hydrogen is the spin species of choice for most MRI applications and for example, the Larmor frequency f₀ for hydrogen nuclei in a 1.5 T magnetic field is 63.8 MHz.

MRI takes advantage of this phenomenon by subjecting an object to be imaged (such as human tissue) to a uniform magnetic field (polarizing field B₀) along a z direction, and then subjecting the object to a magnetic field (excitation field B₁) that is in the x-y plane and that is near the Larmor frequency such that the net aligned moment, M_{z}, may be rotated, or “tipped”, into the x-y plane to produce a net transverse magnetic moment Mₜ. After the excitation signal B₁ (RF excitation pulse) is terminated, a nuclear magnetic resonance (NMR) signal is emitted by the excited spins and this signal is detected.

In MRI systems, the excited spins induce an oscillating sine wave signal in a receiving coil. The frequency of this signal is near the Larmor frequency, and its initial amplitude, A₀, is determined by the magnitude of the transverse magnetic moment Mₜ. The amplitude, A, of the emitted NMR signal decays in an exponential fashion with time, t. The decay constant 1/T*2 depends on the homogeneity of the magnetic field and on T₂, which is referred to as the “spin-spin relaxation” constant, or the “transverse relaxation” constant. The T₂ constant is inversely proportional to the exponential rate at which the aligned precession of the spins would dephase after removal of the excitation signal B₁ in a perfectly homogeneous field. The practical value of the T₂ constant is that tissues have different T₂ values and this can be exploited as a means of enhancing the contrast between such tissues.

Another important factor that contributes to the amplitude A of the NMR signal is referred to as the spin-lattice relaxation process that is characterized by the time constant T₁. It describes the recovery of the net magnetic moment M to its equilibrium value along the axis of magnetic polarization (z). The T₁ time constant is longer than T₂, much longer in most substances of medical interest. As with the T₂ constant, the difference in T₁ between tissues can be exploited to provide image contrast.

When utilizing the received NMR signals to produce images, it is necessary to elicit NMR signals from specific locations in the subject, which is accomplished by employing magnetic fields (Gx, Gy, and Gz) that have the same direction as the polarizing field B₀, but which have a gradient along the respective x, y and z axes. By controlling the strength of these gradients during each NMR cycle, the spatial distribution of spin excitation can be controlled and the location of the resulting NMR signals can be identified. The resulting set of received NMR signals can be digitized and processed to reconstruct an image of the object using one of many well known reconstruction techniques.

The ability to depict anatomy and pathology by MRI is critically dependent on the contrast, or difference in signal intensities between the target and background tissues. In order to maximize contrast, it is necessary to suppress the signal intensities of the background tissues. For instance, small blood vessels are much better depicted by the techniques of magnetic resonance angiography (MRA) when the signal intensities of fat and muscle (background tissues) are minimized.

To enhance the diagnostic capability of MRA a contrast agent such as gadolinium can be injected into the patient prior to the MRA scan. As described in U.S. Pat. No. 5,417,213 contrast enhanced (CE) MRA attempts to acquire the central k-space views at the moment the bolus of contrast agent is flowing through the vasculature of interest. Collection of the central lines of k-space during peak arterial enhancement is key to the success of a CEMRA exam. If the central lines of k-space are acquired prior to the arrival of contrast, severe image artifacts can limit the diagnostic information in the image. Alternatively, arterial images acquired after the passage of the peak arterial contrast are sometimes obscured by the enhancement of veins. In many anatomic regions, such as the carotid or renal arteries, the separation between arterial and venous enhancement can be as short as 6 seconds.

The ability to time the arrival of contrast in the vasculature of interest varies considerably and it is helpful in many applications to acquire a series of MRA images in a dynamic study which depicts the separate enhancement of arteries and veins. Such a temporal series of images is also useful for observing delayed vessel filling patterns caused by disease. This requirement has been partially addressed by acquiring a series of time resolved images using a 3D “Fourier” acquisition as described by Korosec F., Frayne R, Grist T., Mistretta C., “Time-Resolved Contrast-Enhanced 3D MR Angiography”, Magn. Reson. Med. 1996; 36:345-351 and in U.S. Pat. No. 5,713,358. More recently, time-resolved MRA images have been acquired using a three-dimensional projection reconstruction method as described in U.S. Pat. No. 6,487,435 entitled “Magnetic Resonance Angiography Using Undersampled 3D Projection Imaging”.

With CEMRA image studies the usual practice is to acquire at least one image prior to the injection of contrast into the patient. This pre-contrast image is used as a mask that is subtracted from the contrast enhanced images to remove the signal from surrounding non-vascular tissues and fat. While this technique can be very effective, it does have two disadvantages. First, it extends the time of the scan and it requires that the patient be immobilized so that the mask image is precisely registered with the contrast enhanced images from which it is subtracted. Any misregistration results in distracting image artifacts that may interfere with the diagnostic utility of the angiogram. The subtraction of two images also increases the standard deviation of the noise signal, reducing the signal-to-noise ratio (SNR) by the square root of 2.

A unique property of MRI is the ability to selectively image different chemical species by virtue of what is known as the chemical shift phenomenon. The specific frequency that a hydrogen proton absorbs is dependent not only on the applied magnetic filed B₀, but also on its surroundings. For example, in the human body, the bulk of the hydrogen MR signals arise from two sources: water and fat, with fat exhibiting a Larmor frequency that is separated from the water frequency by approximately 3.5 ppm. At a field strength of 2 Tesla this equates to a frequency separation of about 280 Hz in the NMR spectrum. Silicone also exhibits a chemical shift of approximately 5 ppm. This chemical shift has been exploited by a number of different techniques used to suppress signals from undesired tissues or to enhance signals from target tissues.

Various techniques for suppression of fat, generally referred to as FATSAT, are well known in the art. Fat suppression is usually achieved by placing a narrow band spectral suppression pulse before the imaging sequence. This pre-pulse is quickly followed by the imaging sequence so that the fat protons do not have time to relax back to their equilibrium magnetization which remains dispersed (saturated) and unable to contribute signal to the image.

Reference is now made to FIG. 2, which is an illustration of a prior-art 3D gradient-echo motion compensated pulse sequence having a frequency selective simple gaussian FATSAT spectral suppression pulse, which is centered on or tuned to the fat frequency. The double-headed arrow labeled Tp represents the pre-saturation sequence and the double-headed arrow labeled TR represents the imaging sequence. The graph labeled RF represents the RF imaging sequence, which includes a gaussian spectral suppression pre-pulse 2 followed by an imaging RF pulse 3 having a flip angle α.

The graphs labeled Gs, Ge and Gv represent the slice selection gradient, the phase encoding gradient and the viewing, or readout, gradient sequences, respectively. The slice selection gradient sequence includes a three-lobed motion compensated gradient 5, a phase encoding gradient 6 and a rewinder gradient 7. The gradient pulse referenced 4 is a spoiler pulse that is part of the pre-saturation sequence Tp. The phase encoding axis sequence includes a phase encoding gradient 8 and a rewinder gradient 9. The viewing gradient sequence includes a readout gradient 10. The graph labeled S is the NMR signal 11.

Reference is now made to FIG. 3, which is a graph representing a prior-art NMR spectrum of fat and water protons on which a fat gaussian spectral suppression pulse is superimposed. The horizontal axis represents the chemical shift in parts per million (PPM) units. The curve labeled 14 represents the absorption spectrum of fat and water protons. The arrow labeled W indicates the peak absorption of the water protons at 0 ppm and the arrow labeled F indicates the peak of absorption of the fat protons, which is shifted by 3.5 ppm relative to the peak absorption of the water protons. The excitation spectrum of a typical fat gaussian spectral suppression pulse 16 is superimposed on the absorption spectrum curve 14. The gaussian suppression pulse 16 is centered at the peak F and will thus selectively excite the fat protons without substantial excitation of the water protons. Suppression pulses using the Sinc function are also known in the art.

Gaussian and Sinc-type suppression pulses are required to be long in duration in order to achieve a suitably narrow spectral selection. At a field strength of 2 Tesla a typical Sinc suppression pulse may take up to 26 ms.

Reference is now made to FIG. 4, which is an illustration of a prior-art 3D gradient-echo imaging sequence having a frequency selective binomial FATSAT spectral suppression presaturation pulse that is centered on the water frequency. The fat suppression sequence of FIG. 4 uses a 1-3-3-1 binomial suppression pulse which is centered around the water frequency. The use of binomial pulse suppression techniques is disclosed in an article appearing in The Journal of Magnetic Resonance, entitled “Solvent Suppression in Fourier Transform Nuclear Magnetic Resonance” by P. J. Hore (Vol. 55, 1983, pp. 283-300) incorporated herein by reference.

The gradient-echo sequence of FIG. 4 is similar to the gradient-echo sequence of FIG. 2, except that the RF imaging sequence which includes a gaussian spectral suppression pre-pulse 2 of FIG. 4 includes a 1-3-3-1 binomial suppression pulse 1 instead of the gaussian spectral suppression pre-pulse 2. The 1-3-3-1 binomial suppression pulse 1 includes four sub-pulses 1A, 1B, 1C and 1D, which are separated from each other by a pulse separation interval τ.

By choosing the appropriate pulse separation interval τ (dependent upon field strength and chemical species) the binomial pulse 1 exhibits a null excitation at the water frequency which rises to a 90° excitation at the fat frequency.

Reference is now made to FIG. 5, which is a schematic graph illustrating the theoretical excitation spectrum of a prior art 1-3-3-1 binomial suppression pulse as a function of frequency offset from the transmitter frequency. The vertical axis of the graph represents the transverse magnetization M_{xy} wherein full scale corresponds to complete conversion of the z-axis longitudinal magnetization into the x-y plane transverse magnetization. The transverse magnetization curve 40 has a flat excitation null 42 around the transmitter frequency.

The binomial pulse sequence shown in FIG. 4 has a total duration of approximately 5.4 ms at 2 Tesla. This is somewhat shorter than the gaussian pulse 2 of FIG. 2, but requires a high RF power because of the short “hard” pulses.

Suppression techniques generally extend the minimum TR that can be used and result in a reduction in the number of slices that can be imaged in a multi-slice sequence. They are also limited when short TR's are required since rapid, repeated, and incomplete, saturation of the fat frequency inevitably leads to a build up of coherent fat signal resulting in image artifacts.

Methods of spectral-spatial excitation use a carefully designed RF modulation in the presence of an oscillating gradient to excite the target tissues. The result is a simultaneous selection along one spatial axis and the frequency spectrum. The use of Spectral-spatial excitation is disclosed in an article appearing in Magnetic Resonance in Medicine, entitled “Simultaneous Spatial and Spectral selective Excitation” by Craig H. Meyer et al. (Vol. 15, 1990, pp. 287-304), incorporated herein by reference.

FIG. 6 is a graph illustrating imaging sequences designed for a prior art spectral-spatial excitation method. The graph labeled RF represents the RF “fat free” imaging sequence. The gradient sequence labeled G_{z} is a modulated slice selection gradient. The gradient sequences labeled Gₓ and G_{y} are spiral readout gradients. Each of the gradients G_{z}, Gₓ and G_{y} is shown as having a rephasing pulse at the far end of the gradient pulse trains.

The frequency of the modulated gradient is calculated so that, when centered on the water resonance, an excitation null occurs at the fat resonance. In this way only the water resonance is excited. This kind of pulse is usually incorporated directly into the imaging sequence since it is designed to select the desired slice profile only at the water frequency.

Reference is now made to FIG. 7, which is a graph illustrating a prior art rapid gradient-echo pulse sequence using a spectral-spatial pulse with gaussian k-space varying along both k_{z} and k_{ω} as disclosed by Meyer et al. The graphs labeled RFI and RFQ represent the real and the imaginary components of the RF “fat free” imaging sequence, respectively. The gradient sequence labeled G_{z} is a modulated slice selection gradient. The gradient sequences labeled Gₓ is a readout gradient. The gradient sequence G_{y} is a phase encoding gradient. This pulse sequence results in compact spatial and spectral slice profiles (not shown) which are gaussian in shape in the small-tip-angle regime.

Spectral-spatial techniques have the advantage of exciting only the chemical species of interest. Because of this, no sacrifice is necessary on the repetition time (TR). However, spectral-spatial pulses are limited by gradient performance and are especially limited for low field applications where they are prohibitively long in duration. Additionally, careful optimization is required to ensure good spectral selection.

Certain compounds are known to shift the Larmor frequency of spins located in the immediate vicinity of the compound. As disclosed in published US Pat. Appln. No. 2006/0058642 three compounds in the lanthanide family are notable for their chemical shift action. These are dysprosium (Dy), praseodymium (Pr), and europium (Eu) and, when administered to a subject under MRI examination, the Larmor frequency of water spin may be shifted away from the Larmor frequency of fat, making the suppression of fat signals much easier to achieve.

### SUMMARY OF THE INVENTION

The present invention is based on the discovery that imaging agents of various forms can shift the Larmor frequency of adjacent water spins. The present invention recognizes that these shifted water spins can be imaged by using an RF excitation pulse that is centered on the shifted Larmor frequency to perform off-resonance contrast imaging processes.

For example, one such imaging method uses parametric contrast agents, such as those based on gadolinium, which not only shorten the T₁ relaxation of adjacent water spins, but they also produce a chemical shift of the Larmor frequency of those water spins. Other imaging agents can also be used to shift the Larmor frequency of adjacent water spins, such as catheters including a frequency shifting agent. For example, a catheter having a coating or filled with material such as gadolinium, can be used. This provides the potential for passive catheter tracking. However, one drawback is the sensitivity of the gadolinium induced frequency shifts to the orientation of the catheter.

One aspect of the invention is the provision of shaped catheter coatings that shift the resonance frequency and can eliminate the orientation dependence of the frequency shift. For example, the use of a loop in the catheter can overcome these BMS orientation effects.

Another approach may include the application of a spherical-shaped, super-paramagnetic coating to a guidewire placed within a catheter. The immediate surround of such a spherical coating can be visualized in both parallel and perpendicular orientations at the same frequency shift. Different regions adjoining the spherical coating are seen depending on whether a positive or negative frequency offset is used for excitation.

In accordance with one aspect of the present invention, a contrast agent is administered to a subject and an image is acquired using an imaging pulse sequence in which the RF excitation pulse is tuned to the chemically shifted water spins. The imaging acquisition is interleaved with saturation pulse sequences having an RF saturation pulse tuned to fat and water spins that are not chemically shifted by the contrast agent.

A general focus of the invention is to acquire contrast enhanced MRA images without the need to subtract a mask image. The saturation pulse sequences are performed throughout the acquisition at a rate which keeps the signals from tissues surrounding the subject's vasculature suppressed without significantly affecting the signal from blood that contains the contrast agent. In addition, the contrast agent performs its usual function of shortening the T₁ relaxation time of the blood such that many imaging pulse sequences can be performed before the saturated and non-T₁ shortened surrounding tissues recover enough to require another saturation pulse sequence. Thus, the scan is not significantly increased in time.

### BRIEF DESCRIPTION OF THE DRAWINGS

FIG. 1 is a block diagram of an MRI system which employs the present invention;

FIGS. 2-7 are graphic representations of prior-art methods for selectively suppressing or enhancing tissue signals;

FIG. 8 is a graphic representation of an imaging pulse sequence in accordance with the present invention;

FIG. 9 is a graphic representation of a saturation pulse sequence used with the imaging pulse sequence of FIG. 8; and

FIG. 10 is a flow chart of the steps performed by the MRI system of FIG. 1 when practicing the present invention.

### DESCRIPTION OF THE PREFERRED EMBODIMENT

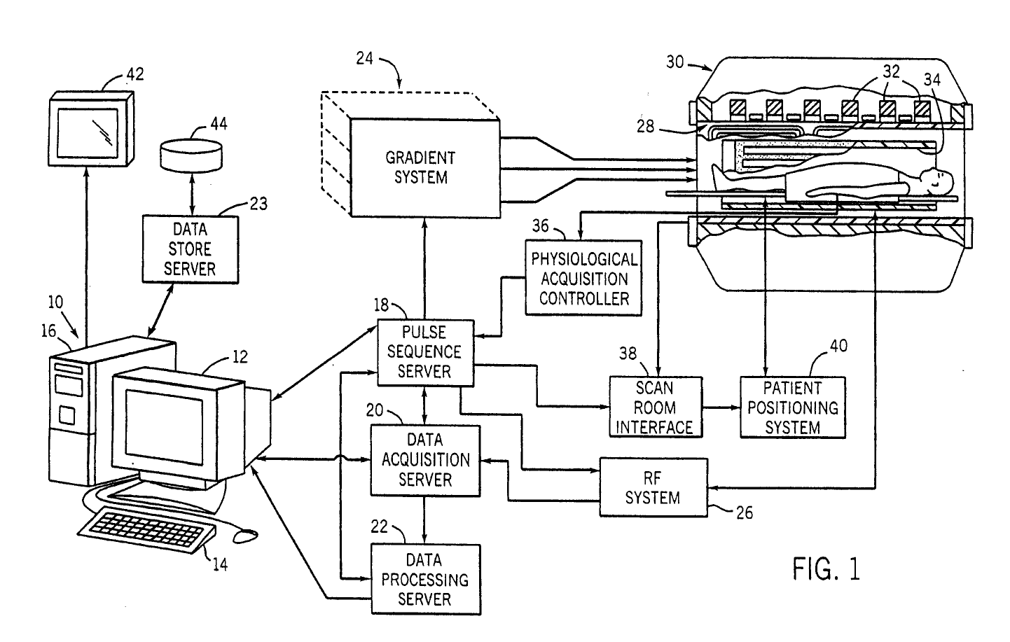

Referring particularly to FIG. 1, an MRI system for use with the present invention includes a workstation 10 having a display 12 and a keyboard 14. The workstation 10 includes a processor 16 that is a commercially available programmable machine running a commercially available operating system. The workstation 10 provides the operator interface that enables scan prescriptions to be entered into the MRI system.

The workstation 10 is coupled to four servers: a pulse sequence server 18; a data acquisition server 20; a data processing server 22; and a data store server 23. In the preferred embodiment the data store server 23 is performed by the workstation processor 16 and associated disc drive interface circuitry. The server 18 is performed by a separate processor and the servers 20 and 22 are combined in a single processor. The workstation 10 and each processor for the servers 18, 20 and 22 are connected to an Ethernet communications network. This network conveys data that is downloaded to the servers 18, 20 and 22 from the workstation 10, and it conveys data that is communicated between the servers.

The pulse sequence server 18 functions in response to instructions downloaded from the workstation 10 to operate a gradient system 24 and an RF system 26. Gradient waveforms necessary to perform the prescribed scan are produced and applied to the gradient system 24 that excites gradient coils in an assembly 28 to produce the magnetic field gradients Gₓ, G_{y} and G_{z} used for position encoding NMR signals. The gradient coil assembly 28 forms part of a magnet assembly 30 that includes a polarizing magnet 32 and a whole-body RF coil 34.

RF excitation waveforms are applied to the RF coil 34 by the RF system 26 to perform the prescribed magnetic resonance pulse sequence. Responsive NMR signals detected by the RF coil 34 are received by the RF system 26, amplified, demodulated, filtered and digitized under direction of commands produced by the pulse sequence server 18. The RF system 26 includes an RF transmitter for producing a wide variety of RF pulses used in MR pulse sequences. The RF transmitter is responsive to the scan prescription and direction from the pulse sequence server 18 to produce RF pulses of the desired frequency, phase and pulse amplitude waveform. The generated RF pulses may be applied to the whole body RF coil 34 or to one or more local coils or coil arrays.

The RF system 26 also includes one or more RF receiver channels. Each RF receiver channel includes an RF amplifier that amplifies the NMR signal received by the coil to which it is connected and a quadrature detector that detects and digitizes the I and Q quadrature components of the received NMR signal. The magnitude of the received NMR signal may thus be determined at any sampled point by the square root of the sum of the squares of the I and Q components:

M=\sqrt{I²+Q²,}

and the phase of the received NMR signal may also be determined:

φ=tan⁻¹Q/I.

The pulse sequence server 18 also optionally receives patient data from a physiological acquisition controller 36. The controller 36 receives signals from a number of different sensors connected to the patient, such as ECG signals from electrodes or respiratory signals from a bellows. Such signals are typically used by the pulse sequence server 18 to synchronize, or “gate”, the performance of the scan with the subject's respiration or heart beat.

The pulse sequence server 18 also connects to a scan room interface circuit 38 that receives signals from various sensors associated with the condition of the patient and the magnet system. It is also through the scan room interface circuit 38 that a patient positioning system 40 receives commands to move the patient to desired positions during the scan.

The digitized NMR signal samples produced by the RF system 26 are received by the data acquisition server 20. The data acquisition server 20 operates in response to instructions downloaded from the workstation 10 to receive the real-time NMR data and provide buffer storage such that no data is lost by data overrun. In some scans the data acquisition server 20 does little more than pass the acquired NMR data to the data processor server 22. However, in scans that require information derived from acquired NMR data to control the further performance of the scan, the data acquisition server 20 is programmed to produce such information and convey it to the pulse sequence server 18. For example, during prescans NMR data is acquired and used to calibrate the pulse sequence performed by the pulse sequence server 18. Also, navigator signals may be acquired during a scan and used to adjust RF or gradient system operating parameters or to control the view order in which k-space is sampled. And, the data acquisition server 20 may be employed to process NMR signals used to detect the arrival of contrast agent in an MRA scan. In all these examples the data acquisition server 20 acquires NMR data and processes it in real-time to produce information that is used to control the scan.

The data processing server 22 receives NMR data from the data acquisition server 20 and processes it in accordance with instructions downloaded from the workstation 10. Such processing may include, for example: Fourier transformation of raw k-space NMR data to produce two or three-dimensional images; the application of filters to a reconstructed image; the performance of a backprojection image reconstruction of acquired NMR data; the calculation of functional MR images; the calculation of motion or flow images, etc.

Images reconstructed by the data processing server 22 are conveyed back to the workstation 10 where they are stored. Real-time images are stored in a data base memory cache (not shown) from which they may be output to operator display 12 or a display 42 that is located near the magnet assembly 30 for use by attending physicians. Batch mode images or selected real time images are stored in a host database on disc storage 44. When such images have been reconstructed and transferred to storage, the data processing server 22 notifies the data store server 23 on the workstation 10. The workstation 10 may be used by an operator to archive the images, produce films, or send the images via a network to other facilities.

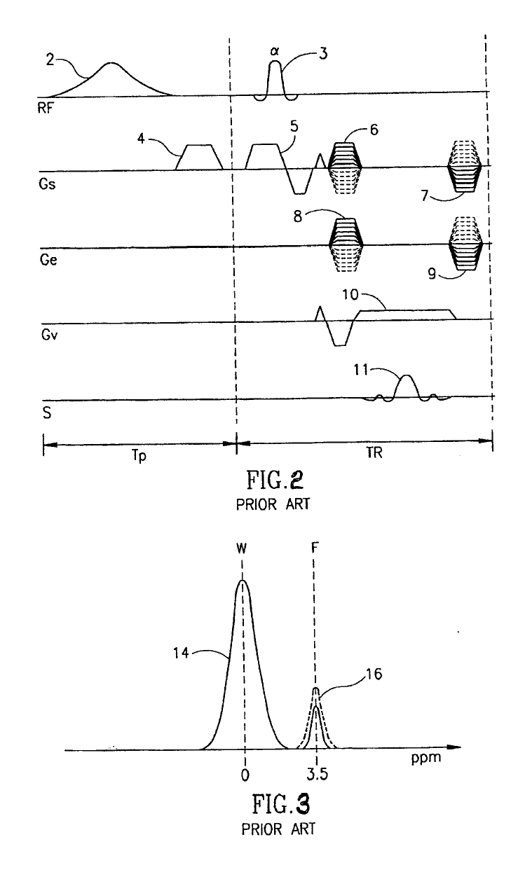

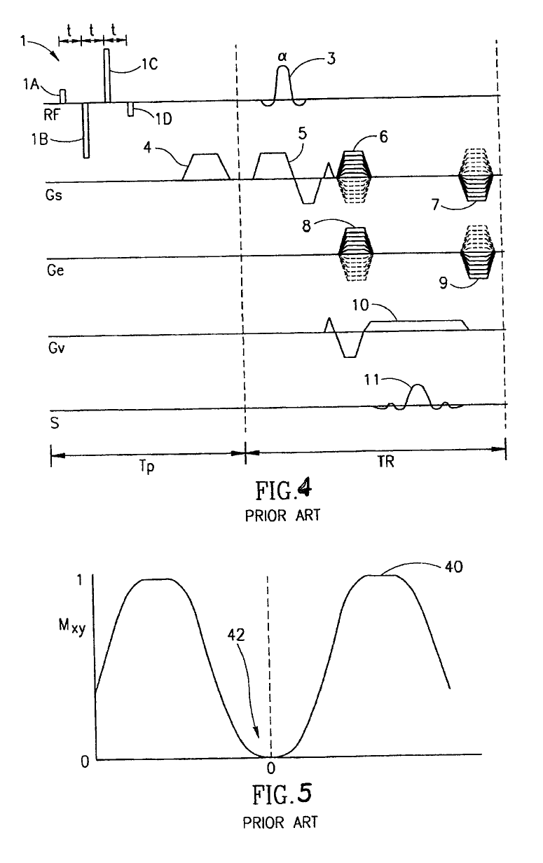

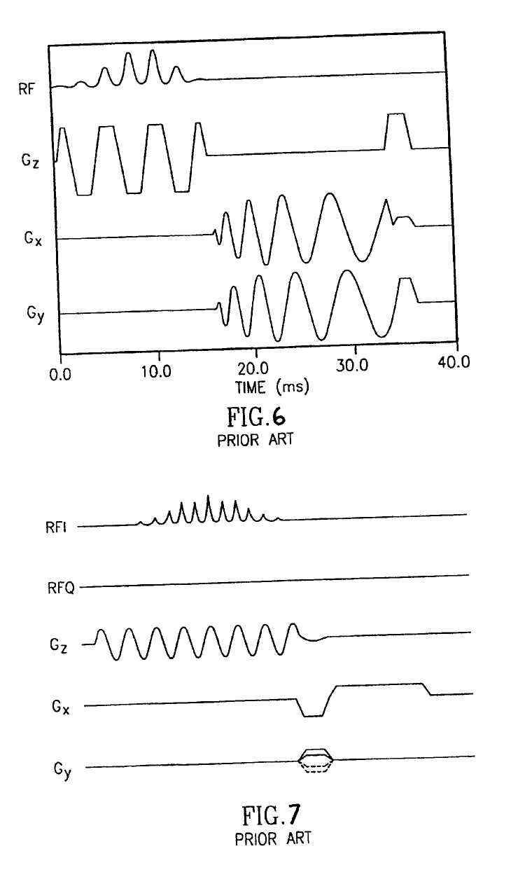

As shown in FIG. 1, the RF system 26 may be connected to the whole body RF coil 34, or as shown in FIG. 2, a transmitter section of the RF system 26 may connect to one RF coil 152A and its receiver section may connect to a separate RF receive coil 152B. Often, the transmitter section is connected to the whole body RF coil 34 and each receiver section is connected to a separate local coil 152B.

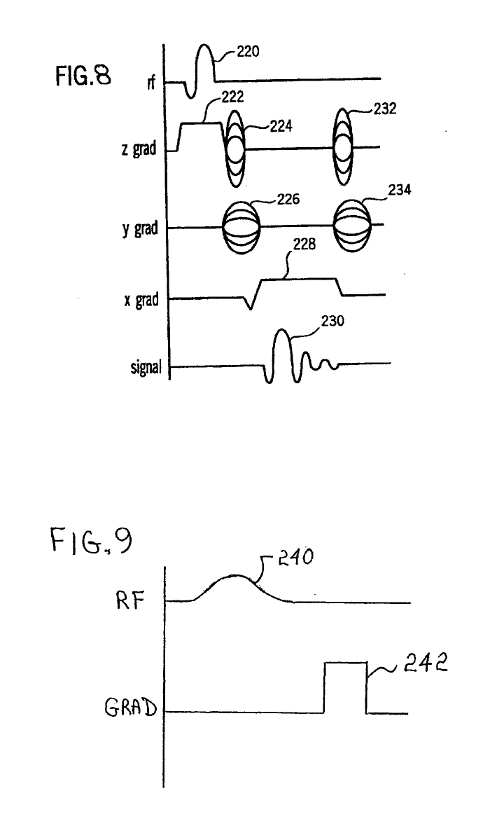

While the present invention may be used with many different imaging pulse sequences, in one embodiment a three-dimensional, spoiled gradient-echo pulse sequence is used with a sampling bandwidth of 83-125 kHz. Referring to FIG. 8, an RF excitation pulse 220 having a flip angle of 15-60 degrees is produced in the presence of a slab select gradient pulse 222 to produce transverse magnetization in the 3D volume of interest. In the alternative, a spectrally-selective, spatially non-selective RF excitation pulse may be used, in which case, no slab select gradient pulse is required. In either case, the RF excitation pulse is followed by a phase encoding gradient pulse 224 directed along the z axis and a phase encoding gradient pulse 226 directed along the y axis. A readout gradient pulse 228 directed along the x axis follows and a partial echo (for example, 60%) NMR signal 230 is acquired and digitized as described above. After the acquisition, rewinder gradient pulses 232 and 234 rephase the magnetization before the pulse sequence is repeated. As is well known in the art, the pulse sequence is repeated and the phase encoding pulses 224 and 226 are stepped through a series of values to sample the 3D k-space.

Sampling along the kₓ axis is performed by sampling the echo signal 230 in the presence of the readout gradient pulse 228 during each pulse sequence. It will be understood by those skilled in the art that only a partial sampling along the kₓ axis is performed and the missing data is computed using a homodyne reconstruction or by zero filling. This enables the echo time (TE) of the pulse sequence to be shortened to 1-2 ms and the pulse repetition rate (TR) to be shortened to 3 to 6 msecs.

The RF excitation pulse 220 in this imaging pulse sequence is tuned to excite water spins that have been chemically shifted by an administered paramagnetic contrast agent. The amount of this chemical shift depends on the type and concentration of the contrast agent, but in the one embodiment gadolinium-DTPA is used and typical frequency shifts are given in Table 1.

TABLE 1

| B₀ | Chemical Shift |
|---|---|
| 1.5 T | 225 Hz |
| 3.0 T | 450 Hz |
| 7.0 T | 1050 Hz |

The excitation pulse 220 may also be spectrally selective to the off-resonance water spins. A number of different approaches can be used to provide spectral selectively, but because the TE and TR times of the imaging pulse sequence should be kept very short, the effectiveness of spectral selectivity is limited.

The suppression of signals from background tissues is achieved primarily by interleaving a saturation pulse sequence with the image pulse sequence repetitions. Referring to FIG. 9, the saturation pulse sequence includes a spectrally selective RF saturation pulse 240, followed by a spoiler gradient pulse 242. The saturation pulse 240 in this embodiment is a frequency selective gaussian saturation pulse with the flip angle of 110 degrees that is tuned to a frequency midway between the Larmor frequency of fat and the Larmor frequency of on-resonance water. Since the saturation pulse sequence is performed far less often than the imaging pulse sequence, the duration of the RF saturation pulse 240 is not as important and it may be extended to insure adequate selection of on-resonance, background tissues without substantially affecting the off-resonance water spins. The spoiler gradient 242 dephases the transverse magnetization produced by the saturation pulse 240.

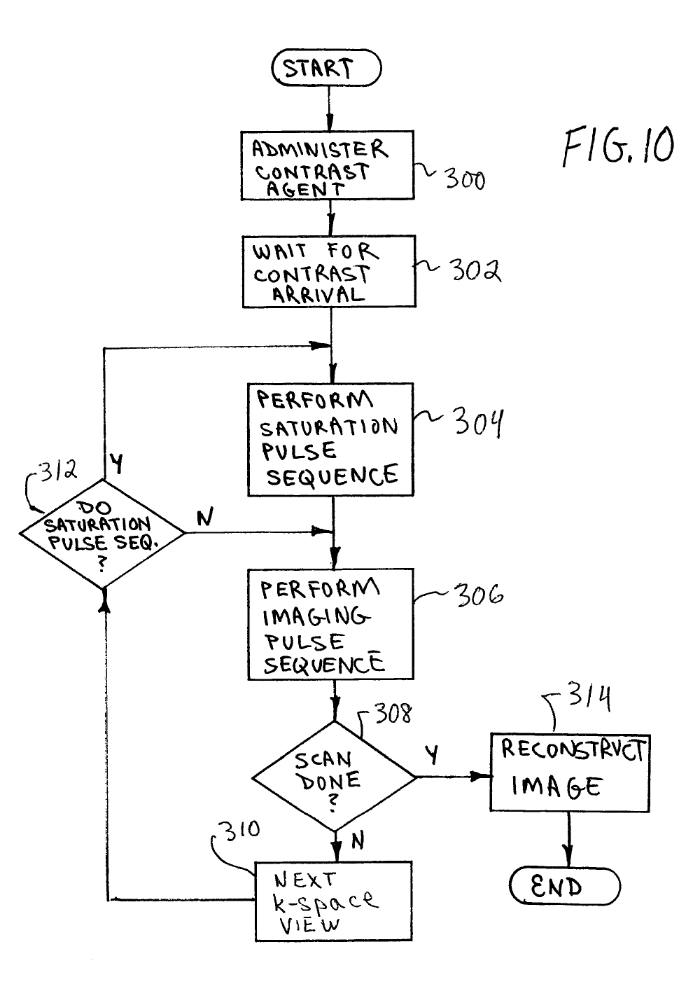

Referring to FIG. 10, a scan is conducted to acquire one or more images using the imaging pulse sequence of FIG. 8. As indicated at process block 300, a contrast agent is first administered and allowed to circulate into the vasculature of interest. A contrast agent that shortens The T1 relaxation time, such as a gadolinium chelate or ultra-small particles of iron oxide (USPIO), is administered. For gadolinium-enhanced MRA, at least 0.2 mmol/kg (body weight) of gadolinium chelate is administered intravenously at a rate of at lease 3 cc/sec. The system pauses until the contrast agent enters the vasculature that is to be imaged as indicated at process block 302 and a loop is then entered in which the image data is acquired.

As indicated at process block 304, the above-described saturation pulse sequence is performed to saturate the on-resonance spins in the region of interest. Then the above-described imaging pulse sequence is performed as indicated at process block 306 to acquire a single view of k-space data. A check is then made at decision block 308 to determine if all the k-space data for the prescribed image (or images) have been acquired. If not, the gradients for the next view are determined as indicated at process block 310 and the system loops back to acquire the next view.

Before acquiring the next view, however, a check is made at decision block 312 to determine if the saturation pulse sequence should be performed first. Typically, from 4 to 128 imaging pulse sequences can be performed before the longitudinal magnetization of surrounding on-resonance background tissues recovers from the previous saturation pulse sequence. The exact number of views acquired between saturation pulse sequences forms part of the scan prescription. Either the imaging pulse sequence is performed, or if the prescribed number of image views has been acquired, the saturation pulse sequence is performed first.

When all the image data has been acquired as determined at decision block 308, the acquired k-space data is used to reconstruct one or more images as indicated at process block 314. A conventional image reconstruction method is used such as a 3 DFT.

It should be apparent that many different imaging pulse sequences can be employed without departing from the spirit of the invention. An important factor, however, is that the RF excitation pulses used in the imaging pulse sequence be tuned to the off-resonance frequency of the contrast enhanced spins. Also, various types of known spectrally selective RF pulses may be used in both the imaging pulse sequence and the saturation pulse sequence.

1. A method for producing an image with a magnetic resonance imaging (MRI) system, the method comprising the steps of:
introducing an imaging agent to the subject that shifts the Larmor frequency of adjacent water spins from a nominal Larmor frequency;
acquiring image data from the subject using an imaging pulse sequence having an RF excitation pulse tuned to the shifted Larmor frequency of the adjacent water spins; and
interleaving saturation pulse sequences with the imaging pulse sequences, the saturation pulse sequences including an RF saturation pulse selectively tuned to saturate one of fat spins and water spins having a Larmor frequency has not been shifted by the imaging agent.

2. The method as recited in claim 1 wherein the RF excitation pulse has a first bandwidth, the RF saturation pulse has a second bandwidth, and the first and the second bandwidths do not overlap.

3. The method as recited in claim 1 wherein the saturation pulse sequence also includes applying a spoiler gradient pulse to dephase transverse magnetization produced by the RF saturation pulse.

4. The method as recited in claim 1 wherein the RF excitation pulse in the imaging pulse sequence is a spectrally selective RF excitation pulse.

5. The method as recited in claim 1 wherein a plurality of imaging pulse sequences is performed following each saturation pulse sequence.

6. The method as recited in claim 1 wherein the imaging agent comprises a catheter including a frequency shifting material.

7. The method of claim 6 wherein the material includes one of gadolinium and iron oxide.

8. The method as recited in claim 1 wherein the catheter includes a spherically shaped portion including a frequency shifting material.

9. The method as recited in claim 8 wherein the material includes one of gadolinium and iron oxide.
